(19) United States
(12) Patent Application Publication
(10) Pub. No.: US 2007/0063183 A1
(43) Pub. Date: Mar. 22, 2007

(54) Substrate having silicon dots

(75) Inventors: Kenji Kato, Kyoto-shi (JP); Atsushi Tomyo, Kyoto-shi (JP); Eiji Takahashi, Kyoto-shi (JP); Takashi Mikami, Kyoto-shi (JP); Tsukasa Hayashi, Kyoto-shi (JP)

Correspondence Address: RADER FISHMAN & GRAUER PLLC, LION BUILDING, 1233 20TH STREET N.W., SUITE 501, WASHINGTON, DC, 20036, US

(73) Assignee: NISSIN ELECTRIC CO., LTD.

(21) Appl. No.: 11/523,039

(22) Filed: Sep. 19, 2006

(30) Foreign Application Priority Data
Sep. 20, 2005 (JP) 2005-271428

(51) Int. Cl. H01L 31/00; H01L 29/06

(52) U.S. Cl. 257/14; 257/23

(57) ABSTRACT

A substrate having silicon dots wherein at least one insulating layer and at least one group of silicon dots are formed on a substrate selected from a non-alkali glass substrate and a substrate made of a polymer material.

### CROSS REFERENCE TO RELATED APPLICATION

This invention is based on Japanese Patent Application No. 2005-271428 filed in Japan on Sep. 20, 2005, the entire content of which is hereby incorporated by reference.

### BACKGROUND OF THE INVENTION

1. Field of the Invention

The present invention relates to a substrate having silicon dots (i.e., so-called silicon nanoparticles) having a size of, e.g., a few nanometers that can be used as electronic device materials for single-electron devices and the like, and light emission materials and others.

2. Description of the Related Art

The substrate having silicon dots can be used for forming an electronic device (e.g., memory element formed using a charge storing capability of silicon dot), a light emission element and the like.

Known methods of forming silicon dots include a CVD method wherein a material gas is supplied into a CVD chamber, and silicon dots (silicon nanoparticles) are formed on a heated substrate (see JP2004-179658A).

JP2004-349341A discloses that silicon aerosol is formed in a diluted silane gas in a high temperature furnace at about 950° C. and the aerosol is oxidized at a high temperature of about 1000° C., whereby silicon dots are produced with an oxidized film formed thereover.

The substrate having silicon dots can be produced by depositing the silicon dots formed by the foregoing technique on the substrate.

However, when forming a substrate having silicon dots by such silicon dot forming method, the method inevitably uses substrates which are expensive and excellent in resistance to thermal deformation and in heat resistant chemical stability such as silicon substrates, quartz glass substrates, etc. Thus, electronic devices, light emission elements and the like using a substrate having silicon dots and employing such expensive substrates are expensive as a matter of course.

Such substrates as silicon substrates, quartz glass substrates, etc. of large size are difficult to obtain in the market so that this prevents the enlargement of substrate having silicon dots.

### SUMMARY OF THE INVENTION

It is an object of the present invention to provide a substrate having silicon dots which is inexpensive and which can be formed with a large area, compared with a substrate having silicon dots formed using silicon substrates, quartz glass substrates and like substrates, etc.

It is another object of the present invention to provide a substrate having silicon dots which is such substrate and which can be easily used in forming electronic devices and the like.

The present invention provides a substrate having silicon dots in which at least one insulating layer and at least one group of silicon dots are formed on a substrate (base substrate) selected from a non-alkali glass substrate and a substrate made of a polymer material.

The foregoing and other objects, features, aspects and advantages of the present invention will become more apparent from the following detailed description when taken in conjunction with accompanying drawings.

### BRIEF DESCRIPTION OF THE DRAWINGS

FIG. 1 is a schematic section view showing an example of the substrate having silicon dots according to the invention.

FIG. 2 is a schematic section view showing an another example of the substrate having silicon dots according to the invention.

FIG. 3 is a schematic section view showing a further example of the substrate having silicon dots according to the invention.

FIG. 4 is a schematic section view showing an additional example of the substrate having silicon dots according to the invention.

FIG. 5. schematically shows a structure of an example of a silicon dot forming apparatus.

FIG. 6. is a block diagram showing an example of an optical emission spectroscopic analyzer for plasma.

FIG. 7. is a block diagram showing a circuit example capable of controlling an amount of exhaust gas (internal pressure of vacuum chamber) with an exhaust device.

FIG. 8 shows another example of formation of silicon dots.

FIG. 9 shows a positional relationship between a target substrate for forming a silicon film, electrodes and the like.

FIG. 10 is a schematic view showing an example of an apparatus for forming a substrate having silicon dots where an insulating layer forming chamber is communicated with a silicon dot forming chamber.

### DESCRIPTION OF THE PREFERRED EMBODIMENTS

Preferred embodiments of the substrate having silicon dots according to the invention are fundamentally those having an insulating layer and silicon dots formed on a non-alkali glass substrate or a substrate made of a polymer material.

The term “silicon dot” used herein is generally called “silicon nanoparticle” having a size of less than 100 nanometers (100 nm). For example, the silicon dots are those having a particle size of a few nanometers to dozens of nanometers. The lower size limit of silicon dot is not restricted, but generally about 1 nm (nanometer) in view of difficulty in formation.

A silicon dot formation target substrate may be a non-alkali glass substrate, a substrate made of a polymer a material or the like.

These substrates are low in heat resistance in retaining a physical stability (stability in scarcely causing distortion) and a chemical stability (scarcely causing chemical change), compared with highly heat resistant substrates, such as quartz glass substrates.

For example, compared with highly heat resistant substrates such as quartz glass substrates, these substrates have a heat resistance temperature of 500° C. (500 deg. C.) or lower in retaining a physical stability and a chemical stability. In other words, these substrates can be stably used at 500° C. or lower in forming silicon dots or the like, and as to a lower limit, at 100° C. or higher, or 150° C. or higher or 200° C. or higher although depending on the type of substrate materials.

Polymer materials to be used are selected from highly heat resistant materials such as polycarbonate, polyimide, polyimideamide, polybenzimidazole, etc.

Non-alkali glass substrates, those made of polymer materials and the like are inexpensive compared with quartz glass substrates and substrates of large area can be easily obtained compared with quartz glass substrates and the like.

Insulating materials for forming the insulating layer are, for example, at least one kind of materials selected from silicon oxide, silicon nitride, and mixtures of silicon oxide and silicon nitride.

More specific examples are silicon oxide (typically SiO₂), silicon nitride (typically Si₃N₄) and mixtures of at least two of them (e.g. a mixture of silicon oxide and silicon nitride) (Si—N—O)).

Embodiments of the insulating layer(s) and the group(s) of silicon dots are, for example, as follows.

(1) An embodiment with an insulating layer and a group of silicon dots formed in this order on the base substrate

(2) An embodiment with insulating layers and at lest one group of silicon dots alternately formed on the base substrate.

The base substrate composing the substrate having silicon dots according to the invention is made of a non-alkali glass or made of a polymer material, and can be inexpensively obtained compared with conventional expensive quartz glass substrates or the like. Therefore, an inexpensive substrate having silicon dots can be provided, and an electronic device and a light emission element can be provided at low costs using the substrate having silicon dots.

Such substrate made of a non-alkali glass or made of a polymer material even with a comparatively large area is available at low costs compared with conventional expensive quartz glass substrates or the like. In view of this, it is possible to provide enlarged substrates having silicon dots. Therefore an enlarged electronic device or light emission device can be provided using the enlarged substrate having silicon dots.

The substrate having silicon dots is formed not only with silicon dots on the substrate but with an insulating layer thereon. For example, when the substrate having silicon dots is used for forming an electronic device such as a charge memory element, the insulating layer is usable for preventing charge dissipation or for withstanding voltage.

When the substrate having silicon dots is used, for example, in formation of a light emission element or in formation of a light emission device, the insulating layer can be used to prevent the contamination of the silicon dots.

In this way, since the substrate having silicon dots holds an insulating layer or insulating layers, the substrate is made to display the ability corresponding to the purpose of the substrate, thus useful in this respect.

The substrate in any of the substrates having silicon dots may be given the same dimensions and the same shape as, e.g., commercially available silicon wafers such that a conventional substrate transfer machine, a substrate holder and the like may be ready to use, or that conventional means for manufacturing an electronic device, a light emission element or the like can be used.

Typical example of the same shape as those of commercially available silicon wafers is a circular disk shape having a cutout for determining the position of the disk and for determining the orientation of the disk. The sizes are, e.g., 8 inches, 12 inches, etc.

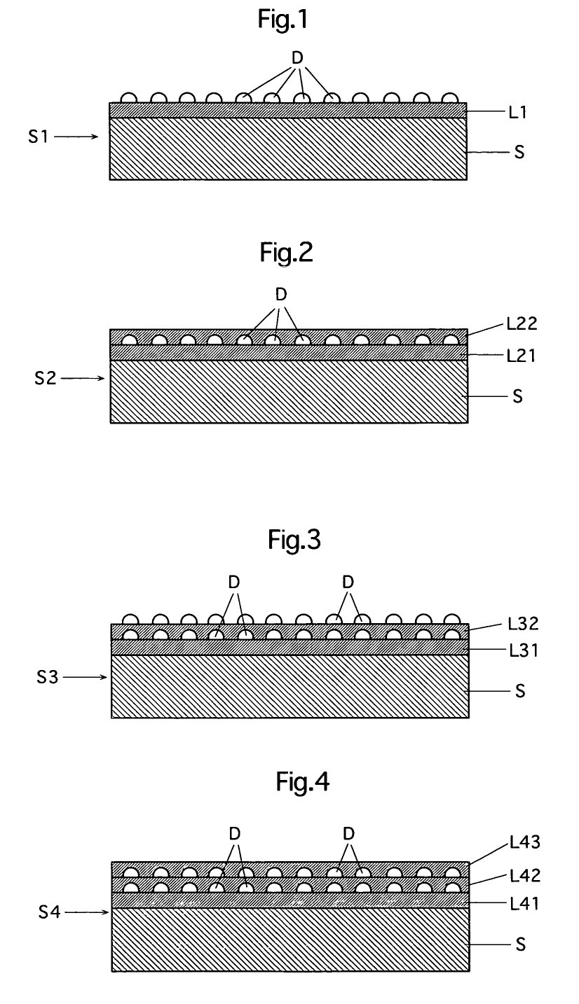

FIGS. 1 to 4 schematically show the sections of examples of the substrate having silicon dots.

A substrate having silicon dots S1 of FIG. 1, a substrate having silicon dots S2 of FIG. 2, a substrate having silicon dots S3 of FIG. 3, and a substrate having silicon dots S4 of FIG. 4, respectively have at least one insulating layer and at least one group of silicon dots D formed on each of the substrates S.

The substrate having silicon dots S1 comprises an insulating layer L1 and silicon dots D formed on the substrate S in this order.

The substrate having silicon dots S2 comprises an insulating layer L21, silicon dots D and an insulating layer L 22 formed alternately on the substrate S in this order. The silicon dots D are covered with the layer L22

The substrate having silicon dots S3 comprises an insulating layer L31, first silicon dots D, an insulating layer L32 and second silicon dots D formed alternately on the substrate S in this order. The first silicon dots D previously formed are covered with the insulating layer L32.

The substrate having silicon dots S4 comprises an insulating layer L41, first silicon dots D, an insulating layer L42, second silicon dots D and an insulating layer L43 formed alternately on the substrate S in this order. The previously formed first silicon dots D are covered with the insulating layer L42, and the later formed second silicon dots D are covered with the insulating layer L43.

In any one of the substrates having silicon dots S1 to S4, the silicon dot is called, e.g., “silicon nanoparticle”. The dot is a minute dot mainly composed of silicon as a main component, and having a particle diameter of less than 100 nanometers (100 nm), e.g. from a few nm to dozens of nm (e.g., about 1 nm to about 20 nm).

In any one of the substrates having silicon dots S1 to S4, the substrate S has a physical heat resistance and a chemical heat resistance in which the substrate is stably usable while retaining a physical stability (stability of, e.g., distortion being scarcely caused) and a chemical stability (stability, e.g., chemical change scarcely occurring) at 500° C. or lower and as to a lower limit, at 100° C. or higher, or 150° C. or higher or 200° C. or higher although depending on the type of materials of the substrate S.

The substrate S is made of a non-alkali glass or a polymer material (polycarbonate, polyimide, polybenzimidazole, polyimideamide, etc.).

In any one of the substrates having silicon dots S1 to S4, the substrate S may be given the same shape and same dimensions as those of a commercially available silicon wafer such that the conventional substrate transfer machine, a substrate holder or the like may be readily usable, or that conventional means for manufacturing an electronic device, a light emission element or the like may be readily usable.

The insulating layers L1, L21, L22, L31, L32, and L41-L43 in the substrates having silicon dots S1 to S4 may be made of silicon oxide (SiO₂), silicon nitride (Si₃N₄), mixtures thereof (Si—N—O) or the like.

Each of the substrates having silicon dots S1 to S4 can be obtained at low costs compared with the substrates having silicon dots using quartz glass substrates or the like. This means that electronic devices, light emission elements and the like can be provided so inexpensively using the substrates having silicon dots S1 to S4.

Such substrate S even of comparatively large area is available at low costs compared with conventional expensive quartz glass substrates or the like. In view of this, it is possible to enlarge the substrates having silicon dots S1-S4 and an electronic device of large size or a large light emission device can be provided using such substrates having silicon dots S1-S4.

The substrates having silicon dots S1 to S4 are formed not only with the silicon dots D on the substrate S but with the insulating layer(s) thereon. Therefore, for example, when the substrate having silicon dots is used for forming an electronic device such as a charge memory element, the insulating layer is usable as a charge dissipation preventing layer or as a layer for withstanding voltage.

For example, when the substrate having silicon dots is used as a light emission element or a light emission device, the insulating layer can be used to prevent the contamination of the silicon dots.

In this way, the substrates having silicon dots S1 to S4 have the insulating layer(s) so that the substrate having silicon dots is made to achieve the capability corresponding to the purpose of the substrate, thus made usable.

The silicon dots D in each of the substrate having silicon dots described above can be produced, for example, as follows.

The formation of silicon dots D is explained, first of all, aside from the formation of insulating layer (the formation of insulating layer will be described later).

<Silicon Dot Forming Method>

The following have been found by the present inventors as to formation of silicon dots.

Plasma is formed from a sputtering gas (i.e., gas for sputtering such as a hydrogen gas), and chemical sputtering (reactive sputtering) is effected on a silicon sputter target with the plasma thus formed so that crystalline silicon dots having substantially uniform particle diameters and exhibiting a substantially uniform density distribution can be formed directly on the silicon dot formation target substrate at a low temperature.

In particular, such a plasma may be employed that a ratio (Si(288 nm)/Hβ) between an emission intensity Si(288 nm) of silicon atoms at a wavelength of 288 nm in plasma emission and an emission intensity Hβ of hydrogen atoms at a wavelength of 484 nm in the plasma emission is 10.0 or lower, preferably 3.0 or lower, or 0.5 or lower, and chemical sputtering with this plasma can form the crystalline silicon dots having substantially uniform particle diameters in a range not exceeding 20 nm (nanometers) (and further 10 nm) and exhibiting a substantially uniform density distribution on the substrate even at a low temperature of 500 deg. C. or lower.

The plasma can be formed by supplying the sputtering gas (e.g., hydrogen gas) to a plasma formation region, and applying a high-frequency power thereto.

Further, the plasma may be formed by applying a high-frequency power to a gas prepared by diluting silane-containing gas with a hydrogen gas, and this plasma may be configured such that a ratio (Si(288 nm)/Hβ) between an emission intensity Si(288 nm) of silicon atoms at a wavelength of 288 nm in plasma emission and an emission intensity Hβ of hydrogen atoms at a wavelength of 484 nm in the plasma emission is 10.0 or lower, preferably 3.0 or lower, or 0.5 or lower. With this plasma, it is possible to form the crystalline silicon dots having substantially uniform particle diameters in a range not exceeding 20 nm (and further 10 nm) and exhibiting a substantially uniform density distribution on a substrate even at a low temperature of 500 deg. C. or lower. In this case, the chemical sputtering of a silicon sputter target with the above plasma may be employed.

In any one of the above cases, the “substantially uniform particle diameters” of the silicon dots represents the case where all the silicon dots have the equal or substantially equal particle diameters as well as the case where the silicon dots have particle diameters which are not uniform to a certain extent, but can be practically deemed as the substantially uniform particle diameters.

For example, it may be deemed without any practical problem that the silicon dots have substantially uniform particle diameters when the particle diameters of the silicon dots fall or substantially fall within a predetermined range (e.g., not exceeding 20 nm, or not exceeding 10 nm).

Also, even in the case where the particle diameters of the silicon dots are spread over a range from 5 nm to 6 nm and a range from 8 nm to 11 nm, it may be deemed without any practical problem that the particle diameters of the silicon dots substantially fall within a predetermined range (e.g., not exceeding 10 nm) as a whole.

In these cases, the silicon dots have the “substantially uniform particle diameters”. In summary, the “substantially uniform particle diameters” of the silicon dots represents the particle diameters which are substantially uniform as a whole from a practical viewpoint.

Based on the above findings, the silicon dots may be formed, e.g., by the following first, second, third or fourth silicon dot forming methods.

(1) First Silicon Dot Forming Method (First Method)

A silicon dot forming method comprising:

a silicon film forming step of supplying a silane-containing gas and a hydrogen gas into a vacuum chamber, applying a high-frequency power to these gases to generate plasma in the vacuum chamber, and forming a silicon film on an inner wall of the vacuum chamber with the plasma; and

a silicon dot forming step of arranging a silicon dot formation target substrate in the vacuum chamber provided with the silicon film formed on the inner wall, supplying a sputtering gas into the vacuum chamber, applying a high-frequency power to the sputtering gas to generate plasma in the vacuum chamber, and effecting chemical sputtering on a sputter target formed of the silicon film with the plasma to form silicon dots on the silicon dot formation target substrate.

In this method, the inner wall of the silicon film forming chamber may be the chamber wall itself or may be an internal wall formed inside the chamber wall or may be a combination thereof.

(2) Second Silicon Dot Forming Method (Second Method)

A silicon dot forming method comprising:

a sputter target forming step of arranging a target substrate in a first vacuum chamber, supplying a silane-containing gas and a hydrogen gas into the first vacuum chamber, applying a high-frequency power to these gases to generate plasma in the first vacuum chamber, and forming a silicon film on the target substrate with the plasma to obtain a silicon sputter target; and

a silicon dot forming step of transferring the silicon sputter target formed in the sputter target forming step from the first vacuum chamber into a second vacuum chamber without exposing the silicon sputter target to an ambient air, arranging a silicon dot formation target substrate in the second vacuum chamber, supplying a sputtering gas into the second vacuum chamber, applying a high-frequency power to the gas to generate plasma in the second vacuum chamber, and effecting chemical sputtering on the silicon film of the silicon sputter target with the plasma to form silicon dots on the silicon dot formation target substrate.

According to the first method, since the silicon film serving as the sputter target is formed on the inner wall of the vacuum chamber, the target of a large area can be obtained as compared with the case where a commercially available silicon sputter target is independently arranged in the vacuum chamber, and therefore the silicon dots can be uniformly formed over a wide area on the substrate.

According to the first and second methods, silicon dots can be formed by employing the silicon sputter target that is not exposed to the ambient air, and thereby silicon dots can be formed while suppressing mixing of unintended impurities. Further, it is possible to form the crystalline silicon dots having substantially uniform particle diameters and exhibiting a substantially uniform density distribution directly on the silicon dot formation target substrate at a low temperature (e.g., with a low substrate temperature of 500 deg. C. or lower).

The silicon film sputtering gas may be typically formed of a hydrogen gas. For example, it may also be formed of a mixture of the hydrogen gas and a rare-gas (at least one kind of gas selected from a group including helium gas (He), neon gas (Ne), argon gas (Ar), krypton gas (Kr) and xenon gas (Xe)).

Thus, according to each of the first and second silicon dot forming methods, the silicon dot forming step can be executed in a manner such that a hydrogen gas is supplied as the sputtering gas into the vacuum chamber accommodating the silicon dot formation target substrate, and the high-frequency power is applied to the hydrogen gas to generate the plasma in the vacuum chamber.

Thereby, the chemical sputtering is effected on the silicon film with the plasma to form the silicon dots of particle diameters not exceeding 20 nm or 10 nm directly on the substrate at a low temperature not exceeding 500 deg. C. (i.e., with a substrate temperature not exceeding 500 deg. C.).

In the first and second methods, the plasma is formed from the silane-containing gas and the hydrogen gas for forming the silicon film serving as the sputter target, and also the plasma is formed from the hydrogen gas for sputtering the silicon film.

In each of these kinds of plasma formation, it is preferable that the plasma exhibits a ratio (Si(288 nm)/Hβ) of 10.0 or lower, and more preferably 3.0 or lower between an emission intensity Si(288 nm) of silicon atoms at a wavelength of 288 nm in the plasma emission and an emission intensity Hβ of hydrogen atoms at a wavelength of 484 nm in the plasma emission. The plasma may exhibit the ratio of 0.5 or lower. The reason for this will be described later in connection with the third and fourth methods.

(3) Third Silicon Dot Forming Method (Third Method)

A silicon dot forming method in which a hydrogen gas is supplied into a vacuum chamber accommodating a silicon sputter target and a silicon dot formation target substrate, and a high-frequency power is applied to the gas to generate, in the vacuum chamber, plasma exhibiting a ratio (Si(288 nm)/Hβ) of 10.0 or lower between an emission intensity Si(288 nm) of silicon atoms at a wavelength of 288 nm in plasma emission and an emission intensity Hβ of hydrogen atoms at a wavelength of 484 nm in the plasma emission. Chemical sputtering is effected on the silicon sputter target with the plasma to form silicon dots of particle diameters not exceeding 20 nm directly on the substrate at a low temperature not exceeding 500 deg. C. (in other words, with a substrate temperature not exceeding 500 deg. C.).

(4) Fourth Silicon Dot Forming Method (Fourth Method)

A silicon dot forming method in which a silane-containing gas and a hydrogen gas are supplied into a vacuum chamber accommodating a silicon dot formation target substrate, a high-frequency power is applied to these gases to generate, in the vacuum chamber, plasma exhibiting a ratio (Si (288 nm)/Hβ) of 10.0 or lower between an emission intensity Si(288 nm) of silicon atoms at a wavelength of 288 nm in plasma emission and an emission intensity Hβ of hydrogen atoms at a wavelength of 484 nm in the plasma emission. Silicon dots of particle diameters not exceeding 20 nm are formed by the plasma directly on the substrate at a low temperature not exceeding 500 deg. C. (in other words, with a substrate temperature not exceeding 500 deg. C.).

In the fourth method, a silicon sputter target may be arranged in the vacuum chamber, and chemical sputtering of the target with the plasma may be additionally employed.

In any one of the foregoing first to fourth methods, when the emission intensity ratio (Si(288 nm)/Hβ) is 10.0 or lower in the plasma, this represents that the plasma is rich in hydrogen atom radicals.

In the first method, the plasma is formed from the silane-containing gas and the hydrogen gas for forming the silicon film serving as the sputter target on the inner wall of the vacuum chamber. In the second method, the plasma is formed from the silane-containing gas and the hydrogen gas for forming the silicon film on the sputter target substrate.

In each of these kinds of plasma formation, when the plasma exhibits the emission intensity ratio (Si(288 nm)/Hβ) of 10.0 or lower, and more preferably 3.0 or lower, or 0.5 or lower, a silicon film (in other words, silicon sputter target) of good quality suitable for forming the silicon dots on the silicon dot formation target substrate is smoothly formed on the inner wall of the vacuum chamber or the sputter target substrate at a low temperature of 500 deg. C. or lower.

In any one of the first, second and third methods, when the plasma used for sputtering the silicon sputter target exhibits the emission intensity ratio (Si(288 nm)/Hβ) of 10.0 or lower, and more preferably 3.0 or lower, or 0.5 or lower, it is possible to form the crystalline silicon dots having substantially uniform particle diameters in a range not exceeding 20 nm (and further 10 nm) and exhibiting a substantially uniform density distribution on the silicon dot formation target substrate at a low temperature of 500 deg. C. or lower (in other words, with a substrate temperature of 500 deg. C. or lower).

In the fourth method, when the plasma produced from the silane-containing gas and the hydrogen gas likewise exhibits the emission intensity ratio (Si(288 nm)/Hβ) of 10.0 or lower, and more preferably 3.0 or lower, or 0.5 or lower, it is possible to form the crystalline silicon dot having substantially uniform particle diameters in a range not exceeding 20 nm (and further 10 nm) and exhibiting a substantially uniform density distribution on the substrate at a low temperature of 500 deg. C. or lower (in other words, at the substrate temperature of 500 deg. C. or lower).

In any one of the methods, if the emission intensity ratio exceeds 10.0, it becomes difficult to grow crystal particles (dots), and a large amount of amorphous silicon is formed on the substrate. Therefore, the emission intensity ratio of 10.0 or lower is preferable. For forming the silicon dots of small particle diameters, the emission intensity ratio is preferably 3.0 or lower, and may be 0.5 or lower.

However, if the emission intensity ratio takes an excessively small value, the growth of the crystal particles (dots) becomes slow, and it takes a long time to attain the required dot particle diameter. If the ratio takes a further small value, an etching effect exceeds the dot growth so that the crystal particles cannot grow. The emission intensity ratio (Si(288 nm)/Hβ) may be substantially 0.1 or more although the value may be affected by various conditions and the like.

The value of emission intensity ratio (Si(288 nm)/Hβ) can be obtained, for example, based on a measurement result obtained by measuring the emission spectrums of various radicals with an optical emission spectroscopic analyzer for plasma.

The control of emission intensity ratio (Si(288 nm)/Hβ) can be performed by controlling the high-frequency power (e.g., frequency or magnitude of the power) applied to the supplied gas(es), vacuum chamber gas pressure during silicon dot formation, and/or an amount of the gas(es) (e.g., hydrogen gas, or hydrogen gas and silane-containing gas) supplied into the vacuum chamber.

According to the first and second silicon dot forming methods (and particularly in the case of using the hydrogen gas as the sputtering gas) as well as the third silicon dot forming method, the chemical sputtering is effected on the silicon sputter target with the plasma exhibiting the emission intensity ratio (Si(288 nm)/Hβ) of 10.0 or lower, preferably 3.0 or lower, or 0.5 or lower. This promotes formation of crystal nucleuses on the substrate, and the silicon dots grow from the nucleuses.

According to the fourth silicon dot forming method, the silane-containing gas and the hydrogen gas are excited and decomposed to promote the chemical reaction and therefore the formation of the crystal nucleuses on the substrate so that the silicon dots grow from the nucleuses. In the fourth method; the chemical sputtering of the silicon sputter target with the plasma may be additionally employed, which also promotes the formation of the crystal nucleuses on the substrate.

Since the crystal nucleus formation is promoted to grow the silicon dots, the nucleuses for growing the silicon dots can be formed relatively readily at a high density even when dangling bonds or steps that can form the nucleuses are not present on the silicon dot formation target substrate.

In a portion where the hydrogen radicals and hydrogen ions are richer than the silicon radicals and silicon ions, and the nucleuses are contained at an excessively large density, desorption of silicon is promoted by a chemical reaction between the excited hydrogen atoms or hydrogen molecules and the silicon atoms, and thereby the nucleus density of the silicon dots on the substrate becomes high and uniform.

The silicon atoms and silicon radicals obtained by decomposition with the plasma and excited by the plasma are absorbed to the nucleuses and grow to the silicon dots by chemical reaction.

During this growth, the chemical reaction of absorption and desorption is promoted owing to the fact that the hydrogen radicals are rich, and the nucleuses grow to the silicon dots having substantial uniform crystal orientations and substantially uniform particle diameters. Owing to the above, the silicon dots having substantially uniform crystal orientations and particle sizes are formed on the substrate at a high density to exhibit a uniform distribution.

The silicon dot forming methods described above are intended to form the silicon dots of minute particle diameters, e.g., of 20 nm or lower, and preferably 10 nm or lower on the silicon dot formation target substrate. In practice, it is difficult to form silicon dots having extremely small particle diameters, and therefore the particle diameters are about 1 nm or more although this value is not restrictive. For example, the diameters may be substantially in a range of 3 nm-15 nm, and more preferably in a range from 3 nm to 10 nm.

In the silicon dot forming methods, the silicon dots can be formed on the substrate at a low temperature of 500 deg. C. or lower (i.e., with the substrate temperature of 500 deg. C. or lower) and, in certain conditions, at a low temperature of 400 deg. C. or lower (i.e., with the substrate temperature of 400 deg. C. or lower). This increases a selection range of the substrate material. For example, the silicon dots can be formed on an inexpensive glass substrate having a low melting point and a heat-resistant temperature of 500 deg. C. or lower.

The silicon dots can be formed at a low temperature as described above. However, if the temperature of the silicon dot formation target substrate is too low, crystallization of the silicon becomes difficult so that it is desired to form the silicon dots at a temperature of about 100 deg. C. or higher, or 150 deg. C. or higher (in other words, with the substrate temperature of about 100 deg. C. or higher or 150 deg. C. or higher) although this depends on other various conditions.

In the fourth silicon dot forming method already described, both the silane-containing gas and the hydrogen gas are used as the plasma formation gases, in which case a gas supply flow rate ratio (silane-containing gas flow rate)/(hydrogen gas flow rate) into the vacuum chamber may be in a range from 1/200 to 1/30. If the ratio is smaller than 1/200, the crystal particles (dots) grow slowly, and a long time is required for achieving a required dot particle diameter. If the ratio is further smaller than the above, the crystal particles (dots) cannot grow. If the ratio is larger than 1/30, it becomes difficult to grow the crystal particles (dots), and a large amount of amorphous silicon is formed on the substrate.

When the supply flow rate of the silane-containing gas is, e.g., in a range from 1 sccm to 5 sccm, it is preferable that (silane-containing gas supply amount (sccm))/(vacuum chamber capacity (liter)) is in a range from 1/200 to 1/30. If this ratio is smaller than 1/200, the crystal particles (dots) grow slowly, and a long time is required for achieving a required dot particle diameter. If the ratio is further smaller than the above, the crystal particles (dots) cannot grow. If the ratio is larger than 1/30, it becomes difficult to grow the crystal particles (dots), and a large amount of amorphous silicon is formed on the substrate.

In any one of the first to fourth silicon dot forming methods, the pressure in the vacuum chamber during the plasma formation may be in a range from about 0.1 Pa to about 10.0 Pa.

If the pressure is lower than 0.1 Pa, the crystal particles (dots) grow slowly, and a long time is required for achieving a required dot particle diameter. If the pressure is smaller than the above, the crystal particles (dots) cannot grow. If the pressure is higher than 10.0 Pa, it becomes difficult to grow the crystal particles (dots), and a large amount of amorphous silicon is formed on the substrate.

When the silicon sputter target is employed in the third silicon dot forming method as well as in the case of employing, in a combined manner, the chemical sputtering of the silicon sputter target in the fourth silicon dot forming method, the following configuration can be employed.

A target substrate is arranged in a sputter target formation vacuum chamber, a silane-containing gas and a hydrogen gas are supplied into the vacuum chamber, a high-frequency power is applied to these gases to generate the plasma in the vacuum chamber, and the plasma forms a silicon film on the target substrate to provide the silicon sputter target.

The silicon sputter target thus obtained can be transferred from the sputter target formation vacuum chamber into the vacuum chamber, in which the silicon dot formation target substrate is arranged, without exposing the silicon sputter target to an ambient air.

When the silicon sputter target is employed in the third silicon dot forming method as well as in the case of employing, in a combined manner, the chemical sputtering of the silicon sputter target in the fourth silicon dot forming method, the following configuration can be employed.

The silicon sputter target may be primarily made of silicon, and may be made of single-crystalline silicon, polycrystalline silicon, microcrystalline silicon, amorphous silicon or a combination of two or more of them.

The silicon sputter target may be appropriately selected depending on uses of the silicon dots from a group including a target not containing impurities, a target containing a very small amount of impurities and a target containing an appropriate amount of impurities exhibiting a predetermined resistivity.

For example, the silicon sputter target not containing impurities and the silicon sputter target containing a very small amount of impurities may be a silicon sputter target in which an amount of each of phosphorus (P), boron (B) and germanium (Ge) is lower than 10 ppm.

The silicon sputter target exhibiting a predetermined resistivity may be a silicon sputter target exhibiting the resistivity from 0.001 ohm·cm to 50 ohm·cm.

In the second and third silicon dot forming methods as well as in the case of employing, in a combined manner, the chemical sputtering of the silicon sputter target in the fourth silicon dot forming method, the silicon sputter target is arranged or located in the vacuum chamber for the silicon dot formation.

This arrangement of the target in the vacuum chamber is merely required to locate the target in the position allowing the chemical sputtering with the plasma, and the target may be arranged, e.g., along the whole or a part of the inner wall surface of the vacuum chamber. It may be independent in the chamber. The arrangement along the inner wall of the chamber and the independent arrangement may be employed in combination.

In the case where the silicon film is formed on the inner wall of the vacuum chamber to provide the silicon sputter target, or the silicon sputter target is arranged along the inner wall surface of the vacuum chamber, the vacuum chamber can be heated to heat the silicon sputter target, and the heated target can be sputtered more readily than the sputter target at a room chamber, and thus can readily form the silicon dots at a high density.

For example, the vacuum chamber may be heated to 80 deg. C. or higher, e.g., by a band heater, heating jacket or the like. In view of economical reason or the like, the upper limit of the heating temperature is, e.g., about 300 deg. C. If O-rings or the like are used in the chamber, the temperature must be lower than 300 deg. C. in some cases depending on heat resistance thereof.

In any one of the silicon dot forming methods, the high-frequency power is applied to the gas(es) supplied into the vacuum chamber by using an electrode which may be of either an inductive coupling type or a capacitive coupling type. When the employed electrode is of the inductive coupling type, it may be arranged in the vacuum chamber or outside the vacuum chamber.

The electrode arranged in the vacuum chamber may be coated with an electrically insulating layer containing, e.g., silicon or aluminum (e.g., silicon film, silicon nitride film, silicon oxide film or alumina film) for maintaining high-density plasma, suppressing mixing of impurities into the silicon dots due to sputtering of the electrode surface and the like.

When the electrode is of the capacitive coupling type, it is recommended to arrange the electrode perpendicularly to the substrate surface (more specifically, perpendicularly to a surface including the silicon dot formation target surface) so that it may not impede the silicon dot formation on the substrate.

In any one of the above cases, the frequency of the high-frequency power for the plasma formation may be in a range from about 13 MHz to about 100 MHz in view of inexpensive processing. If the frequency is higher than 100 MHz, the electric power cost becomes high, and matching becomes difficult when the high-frequency power is applied.

In any one of the above cases, a power density (applied power (W: watt))/(vacuum chamber capacity (L: liter)) is preferably in a range from about 5 W/L to about 100 W/L. If it is lower than 5 W/L, such a situation occurs to a higher extent that the silicon on the substrate becomes amorphous silicon, and does not form crystalline dots. If the density is larger than 100 W/L, a large damage is caused to the silicon dot formation target substrate surface (e.g., a silicon oxide film formed over the silicon wafer and defining the surface of the substrate). The upper limit may be about 50 W/L.

<Silicon Dot Forming Apparatus>

The following first to fourth silicon dot forming apparatuses are provided for implementing the silicon dot forming methods described above.

(1) First Silicon Dot Forming Apparatus

A silicon dot forming apparatus including:

a vacuum chamber having a holder for holding a silicon dot formation target substrate;

a hydrogen gas supply device supplying a hydrogen gas into the vacuum chamber;

a silane-containing gas supply device supplying a silane-containing gas into the vacuum chamber;

an exhaust device exhausting a gas from the vacuum chamber;

a first high-frequency power applying device applying a high-frequency power to the hydrogen gas supplied into the vacuum chamber from the hydrogen gas supply device and the silane-containing gas supplied into the vacuum chamber from the silane-containing gas supply device, and thereby forming plasma for forming a silicon film on an inner wall of the vacuum chamber;

a second high-frequency power applying device applying a high-frequency power to the hydrogen gas supplied into the vacuum chamber from the hydrogen gas supply device after the above silicon film formation, and thereby forming plasma for effecting chemical sputtering on the silicon film used as a sputter target; and

an optical emission spectroscopic analyzer for plasma obtaining a ratio (Si(288 nm)/Hβ) between an emission intensity Si(288 nm) of silicon atoms at a wavelength of 288 nm and an emission intensity Hβ of hydrogen atoms at a wavelength of 484 nm in plasma emission in the vacuum chamber.

This first silicon dot forming apparatus can implement the first silicon dot forming method.

The first silicon dot forming apparatus may further include a control portion comparing the emission intensity ratio (Si(288 nm)/Hβ) obtained by the optical emission spectroscopic analyzer for plasma with a reference emission intensity ratio (Si(288 nm)/Hβ) predetermined within a range not exceeding 10.0 in the process of forming the plasma by at least the second high-frequency power applying device in a group including the first and second high-frequency power applying device, and controlling at least one of a power output of the second high-frequency power applying device, a supply amount of the hydrogen gas supplied from the hydrogen gas supply device into the vacuum chamber and an exhaust amount of the exhaust device such that the emission intensity ratio (Si(288 nm)/Hβ) of the plasma in the vacuum chamber changes toward the reference emission intensity ratio.

In any one of the above cases, the first and second high-frequency power applying devices may partially or entirely share the same structure.

The reference emission intensity ratio may be determined in a range not exceeding 3.0 or 0.5.

(2) Second Silicon Dot Forming Apparatus

A silicon dot forming apparatus including:

a first vacuum chamber having a holder for holding a sputter target substrate;

a first hydrogen gas supply device supplying a hydrogen gas into the first vacuum chamber;

a silane-containing gas supply device supplying a silane-containing gas into the first vacuum chamber;

a first exhaust device exhausting a gas from the first vacuum chamber;

a first high-frequency power applying device applying a high-frequency power to the hydrogen gas supplied into the first vacuum chamber from the first hydrogen gas supply device and the silane-containing gas supplied into the first vacuum chamber from the silane-containing gas supply device, and thereby forming plasma for forming a silicon film on the sputter target substrate;

a second vacuum chamber communicated with the first vacuum chamber in an airtight fashion with respect to an ambient air and having a holder for holding a silicon dot formation target substrate, wherein the sputter target substrate provided with the silicon film formed in the first vacuum chamber is supplied;

a second hydrogen gas supply device supplying a hydrogen gas into the second vacuum chamber;

a second exhaust device exhausting a gas from the second vacuum chamber;

a second high-frequency power applying device applying a high-frequency power to the hydrogen gas supplied from the second hydrogen gas supply device into the second vacuum chamber, and thereby forming plasma for effecting chemical sputtering on the silicon film on the sputter target substrate transferred from the first vacuum chamber into the second vacuum chamber;

an optical emission spectroscopic analyzer for plasma obtaining a ratio (Si(288 nm)/Hβ) between an emission intensity Si(288 nm) of silicon atoms at a wavelength of 288 nm in plasma emission and an emission intensity Hβ of hydrogen atoms at a wavelength of 484 nm in the plasma emission in the second vacuum chamber;

a transferring device transferring the silicon sputter target substrate provided with the silicon film from the first vacuum chamber into the second vacuum chamber without exposing the sputter target substrate provided with the silicon film to the ambient air.

This second silicon dot forming apparatus can implement the second silicon dot forming method.

The second silicon dot forming apparatus may further include a control portion comparing the emission intensity ratio (Si(288 nm)/Hβ) obtained by the optical emission spectroscopic analyzer for plasma with a reference emission intensity ratio (Si(288 nm)/Hβ) predetermined within a range not exceeding 10.0 in the process of forming the plasma by the second high-frequency power applying device, and controlling at least one of a power output of the second high-frequency power applying device, a supply amount of the hydrogen gas supplied from the second hydrogen gas supply device into the second vacuum chamber and an exhaust amount of the second exhaust device such that the emission intensity ratio (Si(288 nm)/Hβ) of the plasma in the second vacuum chamber changes toward the reference emission intensity ratio.

In any one of the above cases, the apparatus may include, for the first vacuum chamber, an optical emission spectroscopic analyzer for plasma obtaining a ratio (Si(288 nm)/Hβ) between an emission intensity Si(288 nm) of silicon atoms at a wavelength of 288 nm and an emission intensity Hβ of hydrogen atoms at a wavelength of 484 nm in plasma emission in the first vacuum chamber. In this case, a control portion similar to the above may be employed for this analyzer.

The first and second high-frequency power applying devices may partially or entirely share the same structure.

The first and second hydrogen gas supply devices may partially or entirely share the same structure.

The first and second exhaust devices may partially or entirely share the same structure.

The transferring device may be arranged, e.g., in the first or second vacuum chamber. The first and second vacuum chambers may be directly connected together via a gate valve or the like, or may be indirectly connected together via a vacuum chamber which is arranged between them and is provided with the foregoing transferring device.

In any one of the above cases, the reference emission intensity ratio may be determined in a range not exceeding 3.0 or 0.5.

The apparatus may be provided with a second silane-containing gas supply device supplying a silane-containing gas into the second vacuum chamber, whereby the apparatus can implement the method of additionally employing the chemical sputtering of the silicon sputter target in the foregoing fourth silicon dot forming method.

(3) Third Silicon Dot Forming Apparatus

A silicon dot forming apparatus including a vacuum chamber having a holder for holding a silicon dot formation target substrate; a silicon sputter target arranged in the vacuum chamber; a hydrogen gas supply device supplying a hydrogen gas into the vacuum chamber; an exhaust device exhausting a gas from the vacuum chamber; a high-frequency power applying device applying a high-frequency power to the hydrogen gas supplied into the vacuum chamber from the hydrogen gas supply device and thereby forming plasma for effecting chemical sputtering on the silicon sputter target; and an optical emission spectroscopic analyzer for plasma obtaining a ratio (Si(288 nm)/Hβ) between an emission intensity Si(288 nm) of silicon atoms at a wavelength of 288 nm in plasma emission and an emission intensity Hβ of hydrogen atoms at a wavelength of 484 nm in the plasma emission in the vacuum chamber.

This third silicon dot forming apparatus can implement the third silicon dot forming method.

The third silicon dot forming apparatus may further include a control portion comparing the emission intensity ratio (Si(288 nm)/Hβ) obtained by the optical emission spectroscopic analyzer for plasma with a reference emission intensity ratio (Si(288 nm)/Hβ) predetermined within a range not exceeding 10.0, and controlling at least one of a power output of the high-frequency power applying device, a supply amount of the hydrogen gas supplied from the hydrogen gas supply device into the vacuum chamber and an exhaust amount of the exhaust device such that the emission intensity ratio (Si(288 nm)/Hβ) of the plasma in the vacuum chamber changes toward the reference emission intensity ratio.

The reference emission intensity ratio may be determined in a range not exceeding 3.0 or 0.5.

(4) Fourth Silicon Dot Forming Apparatus

A silicon dot forming apparatus including a vacuum chamber having a holder for holding a silicon dot formation target substrate; a hydrogen gas supply device supplying a hydrogen gas into the vacuum chamber; a silane-containing gas supply device supplying a silane-containing gas into the vacuum chamber; an exhaust device exhausting a gas from the vacuum chamber; a high-frequency power applying device applying a high-frequency power to the gases supplied into the vacuum chamber from the hydrogen gas supply device and the silane-containing gas supply device, and thereby forming plasma for silicon dot formation; and an optical emission spectroscopic analyzer for plasma obtaining a ratio (Si(288 nm)/Hβ) between an emission intensity Si(288 nm) of silicon atoms at a wavelength of 288 nm in plasma emission and an emission intensity Hβ of hydrogen atoms at a wavelength of 484 nm in the plasma emission in the vacuum chamber.

This fourth silicon dot forming apparatus can implement the fourth silicon dot forming method.

The fourth silicon dot forming apparatus may further include a control portion comparing the emission intensity ratio (Si(288 nm)/Hβ) obtained by the optical emission spectroscopic analyzer for plasma with a reference emission intensity ratio (Si(288 nm)/Hβ) predetermined within a range not exceeding 10.0, and controlling at least one of a power output of the high-frequency power applying device, a supply amount of the hydrogen gas supplied from the hydrogen gas supply device into the vacuum chamber, a supply amount of the silane-containing gas supplied from the silane-containing gas supply device into the vacuum chamber and an exhaust amount of the exhaust device such that the emission intensity ratio (Si(288 nm)/Hβ) of the plasma in the vacuum chamber changes toward the reference emission intensity ratio.

The reference emission intensity ratio may be determined in a range not exceeding 3.0 or 0.5.

The silicon sputter target may be arranged in the vacuum chamber.

In any one of the first to fourth silicon dot forming apparatuses described above, the apparatus may include, as an example of the optical emission spectroscopic analyzer for plasma, a first detecting portion detecting the emission intensity Si(288 nm) of silicon atoms at a wavelength of 288 nm in plasma emission, a second detecting portion detecting the emission intensity Hβ of hydrogen atoms at a wavelength of 484 nm in the plasma emission, and an arithmetic portion obtaining the ratio (Si(288 nm)/Hβ) between the emission intensity Si(288 nm) detected by the first detecting portion and the emission intensity Hβ detected by the second detecting portion.

According to the silicon dot forming methods and apparatuses as described above, the silicon dots having substantially uniform particle diameters can be formed directly on the silicon dot formation target substrate at a low temperature with a uniform density distribution.

Examples of the silicon dot forming apparatus and formation of silicon dots on the substrate will now be described with reference to the drawings.

<Example of Silicon Dot Forming Apparatus (Apparatus A)>

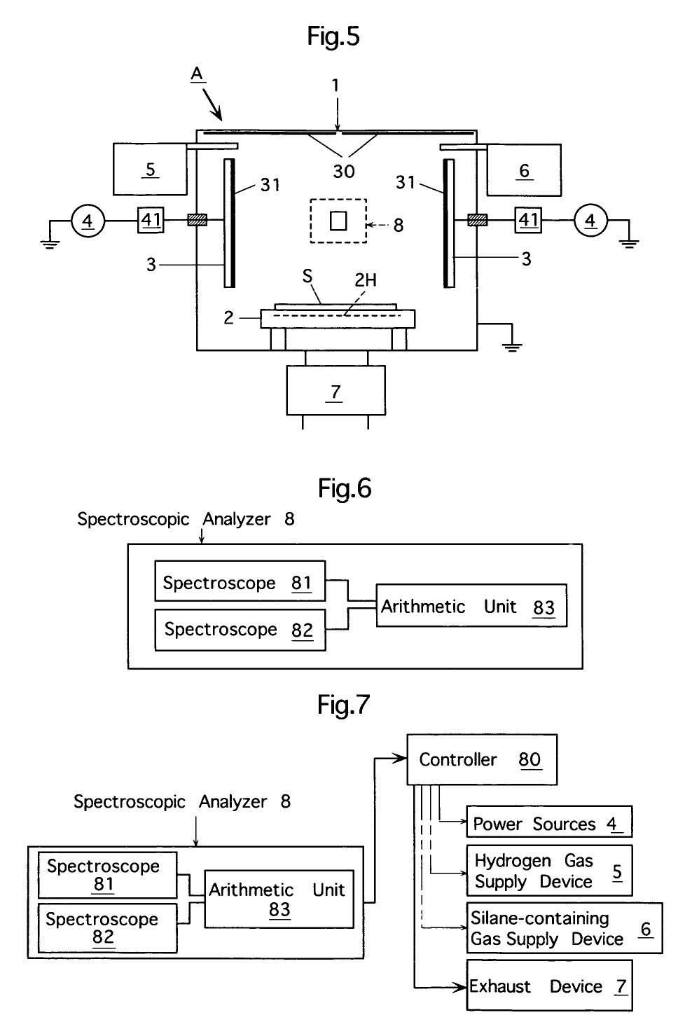

FIG. 5 shows a schematic structure of an example of the silicon dot forming apparatus.

An apparatus A shown in FIG. 1 is employed for forming silicon dots on a plate-like silicon dot formation target substrate (i.e., substrate S in this example), and includes a vacuum chamber 1, a substrate holder 2 arranged in the chamber 1, a pair of discharge electrodes 3 laterally spaced from each other in a region above the substrate holder 2 in the chamber 1, high-frequency power sources 4 for discharge each connected to the discharge electrode 3 via a matching box 41, a gas supply device 5 for supplying a hydrogen gas into the chamber 1, a gas supply device 6 for supplying a silane-containing gas containing a silicon (i.e., having silicon atoms) into the chamber 1, an exhaust device 7 connected to the chamber 1 for exhausting a gas from the chamber 1, an optical emission spectroscopic analyzer 8 for plasma for measuring a state of plasma produced in the chamber 1 and the like. The power sources 4, matching boxes 41 and electrodes 3 form a high-frequency power applying device.

The silane-containing gas may be monosilane (SiH₄), and also may be disilane (Si₂H₆), silicon fluoride (SiF₄), silicon tetrachloride (SiCl₄), dichlorosilane (SiH₂Cl₂) or the like.

The substrate holder 2 is provided with a substrate heating heater 2H.

The electrode 3 is provided at its inner side surface with a silicon film 31 functioning as an insulating layer. Silicon sputter targets 30 are arranged in advance on inner surfaces of a top wall and the like of the chamber 1.

Each electrode 3 is arranged perpendicularly to a surface of the silicon dot formation target substrate S (which will be described later) on the substrate holder 2 (more specifically, perpendicularly to a surface including the surface of the substrate S).

The silicon sputter target 30 can be selected from among commercially available silicon sputter targets (1)-(3) described below depending on the use or the like of the silicon dots to be formed.

(1) A target made of single-crystalline silicon, a target made of polycrystalline silicon, a target made of microcrystalline silicon, a target made of amorphous silicon or a target made of a combination of two or more of them.

(2) A silicon sputter target which is made of one of the materials in the above item (1), and in which a content of each of phosphorus (P), boron (B) and germanium (Ge) is lower than 10 ppm.

(3) A silicon sputter target made of one of the materials in the above item (1), and exhibiting a predetermined resistivity (e.g., a silicon sputter target exhibiting the resistivity from 0.001 ohm·cm to 50 ohm·cm).

The power source 4 is of an output-variable type, and can supply a high-frequency power at a frequency of 60 MHz. The frequency is not restricted to 60 MHz, may be selected from a range, e.g., from about 13.56 MHz to about 100 MHz, or from a higher range.

The chamber 1 and the substrate holder 2 are grounded.

The gas supply device 5 includes the hydrogen gas source as well as a valve, a massflow controller for flow control and the like which are not shown in the figure.

The gas supply device 6 can supply a silane-containing gas such as monosilane (SiH₄), and includes a gas source of the monosilane as well as a valve, a massflow controller for flow control and the like which are not shown in the figure.

The exhaust device 7 includes an exhaust pump as well as a conductance valve for controlling an exhaust flow rate and the like which are not shown in the figure.

The optical emission spectroscopic analyzer 8 for plasma can detect the emission spectrums of products of gas decomposition, and the emission intensity ratio (Si(288 nm)/Hβ) can be obtained based on a result of the detection.

A specific example of the optical emission spectroscopic analyzer 8 for plasma may include, as shown in FIG. 6, a spectroscope 81 detecting the emission intensity Si(288 nm) of silicon atoms at a wavelength of 288 nm in plasma emission in the vacuum chamber 1, a spectroscope 82 detecting the emission intensity Hβ of hydrogen atoms at a wavelength of 484 nm in the plasma emission, and an arithmetic unit 83 obtaining the ratio (Si(288 nm)/Hβ) between the emission intensity Si(288 nm) and the emission intensity Hβ detected by the spectroscopes 81 and 82. Instead of the spectroscopes 81 and 82, photosensors each provided with a filter may be employed.

<Silicon Dot Formation by Apparatus A with Hydrogen Gas>

Description will now be given on an example of formation of the silicon dots on the substrate S by the silicon dot forming apparatus A described above, and particularly on the case where only the hydrogen gas is used as the plasma formation gas.

When forming the silicon dots, the pressure in the vacuum chamber 1 is kept in a range from 0.1 Pa to 10.0 Pa. The vacuum chamber pressure can be sensed, e.g., by a pressure sensor (not shown) connected to the chamber.

First, prior to the silicon dot formation, the exhaust device 7 starts exhausting from the chamber 1. A conductance valve (not shown) of the exhaust device 7 is already adjusted in view of the above pressure from 0.1 Pa to 10.0 Pa for the silicon dot formation in the chamber 1.

When the exhaust device 7 lowers the pressure in the chamber 1 to a predetermined value or lower, the gas supply device 5 starts supplying of the hydrogen gas into the chamber 1, and the power sources 4 apply the power to the electrodes 3 to produce plasma from the supplied hydrogen gas.

From the gas plasma thus produced, the optical emission spectroscopic analyzer 8 for plasma calculates the emission intensity ratio (Si(288 nm)/Hβ), and determines the magnitude of the high-frequency power (e.g., in a range from 1000 watts to 8000 watts in view of cost), the amount of supplied hydrogen gas, the pressure in the chamber 1 and the like such that the above calculated ratio may change toward a range from 0.1 to 10.0, and more preferably to a range from 0.1 to 3.0, or from 0.1 to 0.5.

The magnitude of the high-frequency power is determined such that the power density (applied power (W: watt))/(vacuum chamber capacity (L: liter)) of the high-frequency power applied to the electrodes 3 preferably falls within a range from 5 W/L to 100 W/L, or in a range from 5 W/L to 50 W/L.

After determining the silicon dot formation conditions as described above, the silicon dots are formed according to the conditions.

When forming the silicon dots, the silicon dot formation target substrate S is arranged on the substrate holder 2 in the chamber 1, and is heated by the heater 2H to a temperature (e.g., of 400 deg. C.) not exceeding 500 deg. C. The exhaust device 7 operates to maintain the pressure for the silicon dot formation in the chamber 1, and the gas supply device 5 supplies the hydrogen gas into the chamber 1 so that the power sources 4 apply the high-frequency power to the discharge electrodes 3 to produce the plasma from the supplied hydrogen gas.

In this manner, the ratio (Si(288 nm)/Hβ) between the emission intensity Si(288 nm) of silicon atoms at the wavelength of 288 nm and the emission intensity Hβ of hydrogen atoms at the wavelength of 484 nm in plasma emission falls within the range from 0.1 to 10.0, and more preferably within the range from 0.1 to 3.0, or from 0.1 to 0.5, and thus the plasma having the foregoing reference emission intensity ratio or substantially having the foregoing reference emission intensity ratio is generated.

Chemical sputtering (reactive sputtering) is effected with the above plasma on the silicon sputter targets 30 on the inner wall of the top wall and the like of the chamber 1 so that silicon dots having the particle diameters of 20 nm or lower and exhibiting the crystallinity are formed on the surface of the substrate S.

<Silicon Dot Formation by Apparatus A with Hydrogen Gas and Silane-Containing Gas>

When forming the silicon dots as described above, the silane-containing gas that can be supplied from the gas supply device 6 is not used, and only the hydrogen gas is used. However, the silicon dots can be formed by supplying the silane-containing gas from the gas supply device 6 while supplying the hydrogen gas from the gas supply device 5 into the vacuum chamber 1. When using both the silane-containing gas and the hydrogen gas, the silicon dots can be formed without employing the silicon sputter targets 30.

When employing the silane-containing gas together with the silicon sputter target(s) 30 or without using the target(s) 30, the plasma can be generated such that the ratio (Si(288 nm)/Hβ) between the emission intensity Si(288 nm) of silicon atoms at the wavelength of 288 nm and the emission intensity Hβ of hydrogen atoms at the wavelength of 484 nm in plasma emission falls within the range from 0.1 to 10.0, and more preferably within the range from 0.1 to 3.0, or from 0.1 to 0.5. Even when the silicon sputter target 30 is not employed, the silicon dots having the particle diameters of 20 nm or lower and exhibiting the crystallinity are formed on the surface of the substrate S.

When employing the silicon sputter target 30, the chemical sputtering effected on the silicon sputter target 30 on the inner surface of the top wall and the like with the plasma can be additionally employed so that the silicon dots having the particle diameters of 20 nm or lower and exhibiting the crystallinity are formed on the surface of the substrate S.

In any one of the above cases, the pressure in the vacuum chamber 1 is maintained in a range from 0.1 Pa to 10.0 Pa, and the magnitude of the high-frequency power, amounts of supplied hydrogen gas and silane-containing gas, pressure in the chamber 1 and the like are determined for the silicon dot formation such that the emission intensity ratio (Si(288 nm)/Hβ) calculated by the optical emission spectroscopic analyzer 8 for plasma may attain the value (the reference emission intensity ratio) falling within a range from 0.1 to 10.0, and more preferably a range from 0.1 to 3.0 or from 0.1 to 0.5, or may substantially attain the reference emission intensity ratio.

The magnitude of the high-frequency power is determined such that the power density (applied power (W: watt))/(vacuum chamber capacity (L: liter)) of the high-frequency power applied to the electrodes 3 falls within a range from 5 W/L to 100 W/L, or in a range from 5 W/L to 50 W/L, and the silicon dot formation may be performed under the silicon dot formation conditions thus determined.

The supply flow rate ratio (silane-containing gas flow rate)/(hydrogen gas flow rate) between the silane-containing gas and the hydrogen gas supplied into the vacuum chamber 1 is determined in a range from 1/200 to 1/30. The supply flow rate of the silane-containing gas is, e.g., in a range from 1 sccm to 5 sccm, and the ratio of (silane-containing gas supply flow rate (sccm))/(vacuum chamber capacity (liter)) may be in a range from 1/200 to 1/30. When the supply flow rate of the silane-containing gas is substantially in a range from 1 sccm to 5 sccm, the appropriate supply flow rate of the hydrogen gas is, e.g., in a range from 150 sccm to 200 sccm.

In the silicon dot forming apparatus A described above, each of the electrodes is an electrode of a capacitive coupling type having a flat form, but may be an electrode of an inductive coupling type. The electrode of the inductive coupling type may have various forms such as a rod-like form or a coil-like form. The number of the electrode of the inductive coupling type is not restricted.

In the case of employing an electrode of the inductive coupling type as well as the silicon sputter target, the silicon sputter target may be arranged along the whole of or a part of the inner surface of the chamber wall, may be independently arranged in the chamber or may be arranged in both the manners in spite of whether the electrode is arranged inside the chamber or outside the chamber.

In connection with the apparatus A, the chamber 1 may be heated by means (e.g., band heater, heating jacket internally passing heat medium) for heating the vacuum chamber 1 (although not shown in the figure) to heat the silicon sputter target to 80 deg. C. or higher for promoting sputtering of the silicon sputter target.

<Another Example of Control of Vacuum Chamber Inner Pressure or the Like>

When forming the silicon dots as described above, manual operations are performed with reference to the emission intensity ratio obtained by the optical emission spectroscopic analyzer for plasma 8 for controlling the output of the output-variable power sources 4, the hydrogen gas supply amount of the hydrogen gas supply device 5 (or the hydrogen gas supply amount of the hydrogen gas supply device 5 and the silane-containing gas supply amount of the silane-containing gas supply device 6), the exhaust amount of the exhaust device 7 and others.

However, the emission intensity ratio (Si(288 nm)/Hβ) obtained by the arithmetic unit 83 of the be applied to a controller 80 as shown in FIG. 7. The controller 80 may be configured as follows.

The controller 80 determines whether the emission intensity ratio (Si(288 nm)/Hβ) applied from the arithmetic unit 83 is the predetermined reference emission intensity ratio or not.

When it is different from the reference emission intensity ratio, the controller 80 can control at least one of the output of the output-variable power sources 4, the supply amount of the hydrogen gas supplied from the hydrogen gas supply device 5, the supply amount of the silane-containing gas supplied from the silane-containing gas supply device 6 and the exhaust amount of the exhaust device 7.

As a specific example, the controller 80 may be configured such that the controller 80 controls the exhaust amount of the exhaust device 7 by controlling the conductance valve thereof, and thereby controls the gas pressure in the vacuum chamber 1 to attain the foregoing reference emission intensity ratio.

In this case, the output of the output-variable power sources 4, the hydrogen gas supply amount of the hydrogen gas supply device 5 (or the hydrogen gas supply amount of the hydrogen gas supply device 5 and the silane-containing gas supply amount of the silane-containing gas supply device 6) and the exhaust amount of the exhaust device 7 are controlled based on the initial values of the power output, the hydrogen gas supply amount (or supply amounts of the hydrogen gas and the silane-containing gas) and the exhaust amount which can achieve the reference emission intensity ratio or a value close to it, and are determined in advance by experiments or the like.

When determining the above initial values, the exhaust amount of the exhaust device 7 is determined such that the pressure in the vacuum chamber 1 falls within the range from 0.1 Pa to 10.0 Pa.

The output of the power source 4 is determined such that the power density of the high-frequency power applied to the electrode 3 may fall within the range from 5 W/L to 100 W/L, or from 5 W/L to 50 W/L.

When both the hydrogen gas and silane-containing gas are used as the gases for plasma formation, the gas supply flow rate ratio (silane-containing gas flow rate)/(hydrogen gas flow rate) into the vacuum chamber 1 is determined in a range from 1/200 to 1/30. For example, the supply flow rate of the silane-containing gas 1 sccm-5 sccm, and (silane-containing gas supply flow rate (sccm))/(vacuum chamber capacity (liter)) is determined in a range from 1/200 to 1/30.

The output of the power source 4 and the hydrogen gas supply amount of the hydrogen gas supply device 5 (or the hydrogen gas supply amount of the hydrogen gas supply device 5 and the silane-containing gas supply amount of the silane-containing gas supply device 6) will be maintained at the initial values thus determined, and the exhaust amount of the exhaust device 7 is controlled by the controller 80 to attain the reference emission intensity ratio.

<Another Example of Silicon Sputter Target>

In the method of forming the silicon dots as described above, the silicon sputter target is formed of a commercially available target, and is arranged in the vacuum chamber 1 in an independent step. However, by employing the silicon sputter target that has not been exposed to an ambient air, it is possible to form the silicon dots that are further protected from unintended mixing of impurities.

More specifically, in the apparatus A described above, the hydrogen gas and silane-containing gas are supplied into the vacuum chamber 1 when the substrate S is not yet arranged therein, and the power sources 4 apply the high-frequency power to these gases to form the plasma, which forms a silicon film on the inner wall of the vacuum chamber 1.

When forming the silicon film, it is preferable to heat the chamber wall by an external heater. Thereafter, the substrate S is arranged in the chamber 1, and the chemical sputtering is effected on the sputter target formed of the silicon film with the plasma produced from the hydrogen gas so that the silicon dots are formed on the substrate S as described above.

In the process of forming the silicon film to be used as the silicon sputter target, it is desired for forming the silicon film of good quality that the emission intensity ratio (Si(288 nm)/Hβ) in the plasma falls within the range from 0.1 to 10.0, and more preferably within the range from 0.1 to 3.0, or from 0.1 to 0.5.

<Other Examples of Silicon Dot Forming Method and Apparatus)

Another method may be employed as described below.

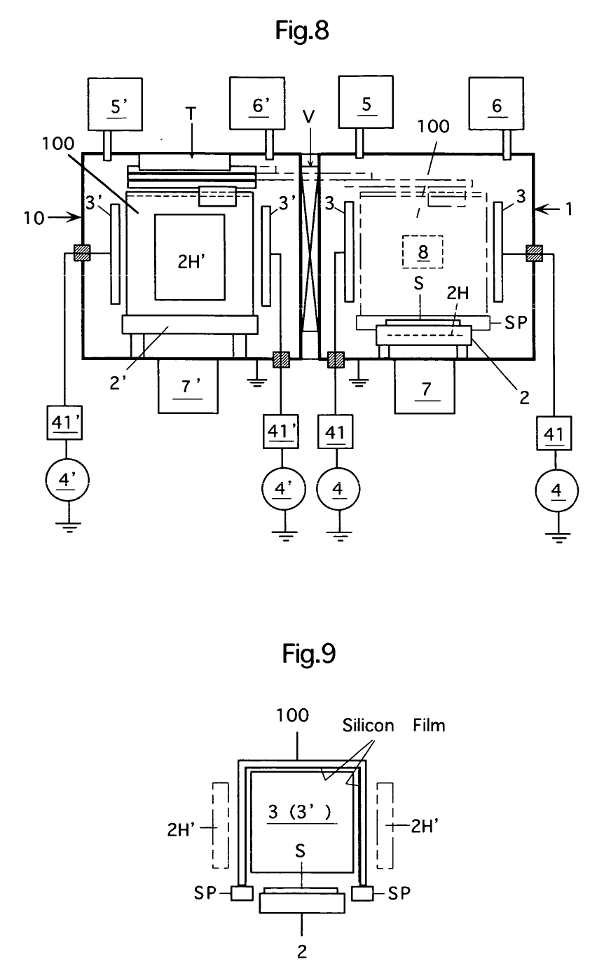

As schematically shown in FIG. 8, a vacuum chamber 10 for forming a silicon sputter target is communicated with the vacuum chamber 1 via a gate valve V in an airtight fashion with respect to an ambient air.

A target substrate 100 is arranged on a holder 2′ in the chamber 10, and an exhaust device 7′ exhausts a gas from the vacuum chamber 10 to keep a predetermined deposition pressure. A hydrogen gas supply device 5′ and a silane-containing gas supply device 6′ supply the hydrogen gas and the silane-containing gas into the chamber while keeping the predetermined deposition pressure, respectively. Further, an output-variable power sources 4′ apply the high-frequency power to electrodes 3′ in the chamber through matching boxes 41′ to form the plasma. By this plasma, the silicon film is formed on the target substrate 100 heated by a heater 2H′.

Thereafter, the gate valve V is opened, and a transfer device T transfers the target substrate 100 bearing the silicon film into the vacuum chamber 1, and sets it on a base SP in the chamber 1.

Then, the transfer device T returns, and the gate valve V is airtightly closed and one of the silicon dot forming methods already described is executed to form the silicon dots on the substrate S arranged in the chamber 1, using the target substrate 100 bearing the silicon film as the silicon sputter target in the chamber 1.

FIG. 9 shows positional relationships of the target substrate 100 with respect to the electrodes 3 (or 3′), the heater 2H′ in the chamber 10, the base SP in the chamber 1, the substrate S and the like.

The target substrate 100 has a substantially inverted U-shaped section for obtaining the silicon sputter target of a large area as shown in FIG. 9, although it may have another form. The transfer device T can transfer the substrate 100 without colliding the substrate 100 against the electrodes or the like.

The transfer device T may have various structures provided that it can bring the substrate 100 into the vacuum chamber 1 and can set it therein. For example, the transfer device T may have a structure having an extensible arm for holding the substrate 100.

When forming the silicon film on the target substrate in the chamber 10, it is desired that the emission intensity ratio (Si(288 nm)/Hβ) of the plasma falls within the range from 0.1 to 10.0, and more preferably within the range from 0.1 to 3.0, or from 0.1 to 0.5.

In this case, the output of the power sources 4′ in the vacuum chamber 10, the hydrogen gas supply amount of the hydrogen gas supply device 5′, the silane-containing gas supply amount of the silane-containing gas supply device 6′ and the exhaust amount of the exhaust device 7′ are controlled similarly to the case of forming the silicon dots on the substrate S with the hydrogen gas and the silane-containing gas. Manual control may be performed, and automatic control with the controller may also be performed.

In connection with the transfer device, a vacuum chamber provided with a transfer device may be arranged between the vacuum chambers 10 and 1, and the chamber provided with the transfer device may be connected to each of the chambers 10 and 1 via a gate valve.

### EXPERIMENTAL EXAMPLES

Experimental examples for forming a substrate having silicon dots will be described

### (1) Experimental Example 1

Experimental examples for forming a substrate having silicon dots will be described (1)

A silicon dot forming apparatus of the type shown in FIG. 5 was used. However, the silicon sputter target was not employed, and the silicon dots were directly formed on the substrate with a hydrogen gas and a monosilane gas.

Dot formation conditions were as follows:
Substrate: non-alkali glass substrate coated with oxide film (SiO₂)
Chamber capacity: 180 liters
High-frequency power source: 60 MHz, 6 kW
Power density: 33 W/L
Substrate temperature: 400 deg. C. (400° C.)
Inner pressure of chamber: 0.6 Pa
Silane supply amount: 3 sccm
Hydrogen supply amount: 150 sccm
Si(288 nm)/Hβ: 0.5

In this way, a substrate having silicon dots of the type shown in FIG. 1 was obtained.

The section of the substrate was observed with a transmission electron microscope (TEM), and it was confirmed that the silicon dots having substantially the uniform particle diameters were formed independently from each other, and these silicon dots exhibited a uniform distribution and a high density state.

From the TEM images, the particle diameters of the silicon dots of 50 in number were measured. The average of the measured values was 7 nm, and it was confirmed that the silicon dots of the particle diameters not exceeding 20 nm and particularly not exceeding 10 nm were formed. The dot density was about 1.4×10¹² pcs (pieces)/cm².

### (2) Experimental Example 2

The silicon dot forming apparatus of the type shown in FIG. 5 was used. The hydrogen gas and the monosilane gas were used, and further the silicon sputter target was used. The silicon dots were directly formed on the substrate.

Dot formation conditions were as follows:
Silicon sputter target: amorphous silicon sputter target
Substrate: polycarbonate substrate coated with
oxide film (SiO₂)
Chamber capacity: 180 liters
High-frequency power source: 60 MHz, 4 kW
Power density: 22 W/L
Substrate temperature: 150 deg. C.
Inner pressure of chamber: 0.6 Pa
Silane supply amount: 1 sccm
Hydrogen supply amount: 150 sccm
Si(288 nm)/Hβ: 0.3

In this way, a substrate having silicon dots of the type shown in FIG. 1 was obtained.

The section of the substrate was observed with the transmission electron microscope (TEM), and it was confirmed that the silicon dots having substantially the uniform particle diameters were formed independently from each other, and these silicon dots exhibited a uniform distribution and a high density state.

From the TEM images, the particle diameters of the silicon dots of 50 in number were measured. The average of the measured values was 10 nm, and it was confirmed that the silicon dots of the particle diameters not exceeding 20 nm were formed. The dot density was about 1.0×10¹² pcs/cm².

### (3) Experimental Example 3

The silicon dot forming apparatus of the type shown in FIG. 5 was used. Without use of silane gas, hydrogen gas and silicon sputter target were used. The silicon dots were directly formed on the substrate.

Dot formation conditions were as follows:
Silicon sputter target: single-crystalline silicon sputter target
Substrate: polyimide substrate coated with oxide film (SiO₂)
Chamber capacity: 180 liters
High-frequency power source: 60 MHz, 4 kW
Power density: 22 W/L
Substrate temperature: 200 deg. C.
Inner pressure of chamber: 0.6 Pa
Si(288 nm)/Hβ: 0.2

In this way, a substrate having silicon dots of the type shown in FIG. 1 was obtained.

The section of the substrate was observed with the transmission electron microscope (TEM), and it was confirmed that the silicon dots having substantially the uniform particle diameters were formed independently from each other, and these silicon dots exhibited a uniform distribution and a high density state.

From the TEM images, the particle diameters of the silicon dots of 50 in number were measured. The average of the measured values was 5 nm, and it was confirmed that the silicon dots of the particle diameters not exceeding 20 nm and particularly not exceeding 10 nm were formed. The dot density was about 2.0×10¹² pcs/cm².

### (4) Experimental Example 4

The silicon dot forming apparatus of the type shown in FIG. 5 was used. First, a silicon film was formed on the inner wall of the vacuum chamber 1, and then the silicon dots were formed using the silicon film as the sputter target.

Silicon film formation conditions and dot formation conditions were as follows:

Silicon Film Formation Conditions
Chamber inner wall area: about 3 m²
Chamber capacity: 440 liters
High-frequency power source: 13.56 MHz, 10 kW
Power density: 23 W/L
Inner wall temperature of chamber: 80 deg. C. (heated by heater in chamber)
Inner pressure of chamber: 0.67 Pa
Monosilane supply amount 100 sccm
Hydrogen supply amount: 150 sccm
Si(288 nm)/Hβ: 2.0

Dot Formation Conditions
Substrate: non-alkali glass substrate coated with oxide film (SiO₂)
Chamber capacity: 440 liters
High-frequency power source: 13.56 MHz, 5 kW
Power density: 11 W/L
Inner wall temperature of chamber: 80 deg. C. (heated by heater in chamber)

Substrate temperature: 430 deg. C.
Inner pressure of chamber: 0.67 Pa
Hydrogen supply amount: 150 sccm (monosilane gas was not used)
Si(288 nm)/Hβ: 1.5

In this way, a substrate having silicon dots of the type shown in FIG. 1 was obtained.

The section of the substrate was observed with the transmission electron microscope (TEM), and it was confirmed that the silicon dots having substantially the uniform particle diameters were formed independently from each other, and these silicon dots exhibited a uniform distribution and a high density state. Small dots have diameters from 5 nm to 6 nm, and large dots have diameters of 9 nm-11 nm.

From the TEM images, the particle diameters of the silicon dots of 50 in number were measured. The average of the measured values was 8 nm, and it was confirmed that the silicon dots of the particle diameters not exceeding 10 nm were formed. The dot density was about 7.3×10¹¹ pcs/cm².

### (5) Experimental Example 5

The silicon dot forming apparatus of the type shown in FIG. 5 was used. First, a silicon film was formed on the inner wall of the vacuum chamber 1 under the same silicon film formation conditions as those in the experimental example 4, and then the silicon dots were formed using the silicon film as the sputter target. The dot formation conditions were the same as those of the experimental example 4 except for that the inner pressure of the chamber was 1.34 Pa, and Si(288 nm)/Hβwas 2.5.

In this way, a substrate having silicon dots of the type shown in FIG. 1 was obtained.

The section of the substrate was observed with the transmission electron microscope (TEM), and it was confirmed that the silicon dots having substantially the uniform particle diameters were formed independently from each other, and these silicon dots exhibited a uniform distribution and a high density state.

From the TEM images, the particle diameters of the silicon dots of 50 in number were measured. The average of the measured values was 10 nm, and it was confirmed that the silicon dots of the particle diameters not exceeding 10 nm were formed. The dot density was about 7.0×10¹¹ pcs/cm².

### (6) Experimental Example 6

The silicon dot forming apparatus of the type shown in FIG. 5 was used. First, a silicon film was formed on the inner wall of the vacuum chamber 1 under the same silicon film formation conditions as those in the experimental example 4, and then the silicon dots were formed using the silicon film as the sputter target. The dot formation conditions were the same as those of the experimental example 4 except for that the inner pressure of the chamber was 2.68 Pa, and Si(288 nm)/Hβwas 4.6.

In this way, a substrate having silicon dots of the type shown in FIG. 1 was obtained.

The section of the substrate was observed with the transmission electron microscope (TEM), and it was confirmed that the silicon dots having substantially the uniform particle diameters were formed independently from each other, and these silicon dots exhibited a uniform distribution and a high density state.

From the TEM images, the particle diameters of the silicon dots of 50 in number were measured. The average of the measured values was 13 nm, and it was confirmed that the silicon dots of the particle diameters not exceeding 20 nm were formed. The dot density was about 6.5×10¹¹ pcs/cm².

### (7) Experimental Example 7

The silicon dot forming apparatus of the type shown in FIG. 5 was used. First, a silicon film was formed on the inner wall of the vacuum chamber 1 under the same silicon film formation conditions as those in the experimental example 4, and then the silicon dots were formed using the silicon film as the sputter target. The dot formation conditions were the same as those of the experimental example 4 except for that the inner pressure of the chamber was 6.70 Pa, and Si(288 nm)/Hβwas 8.2.

In this way, a substrate having silicon dots of the type shown in FIG. 1 was obtained.

The section of the substrate was observed with the transmission electron microscope (TEM), and it was confirmed that the silicon dots having substantially the uniform particle diameters were formed independently from each other, and these silicon dots exhibited a uniform distribution and a high density state.

From the TEM images, the particle diameters of the silicon dots of 50 in number were measured. The average of the measured values was 16 nm, and it was confirmed that the silicon dots of the particle diameters not exceeding 20 nm were formed. The dot density was about 6.1×10¹¹ pcs/cm².

<Another Example of Forming a Substrate Having Silicon Dots>

As apparent from the foregoing experimental examples, the substrate having silicon dots S1 of the type shown in FIG. 1 can be produced using a substrate S on which an insulating layer L1 of SiO₂ was formed beforehand, and silicon dots are formed on the layer L1.

However, for example, a chamber for forming an insulating layer may be provided in addition to the silicon dot forming chamber, and an insulating layer may be formed in the chamber for forming an insulating layer. The substrate having the insulating layer formed thereon can be supplied into the silicon dot forming chamber without exposing the substrate to an ambient air and the silicon dots are formed on the insulating layer.

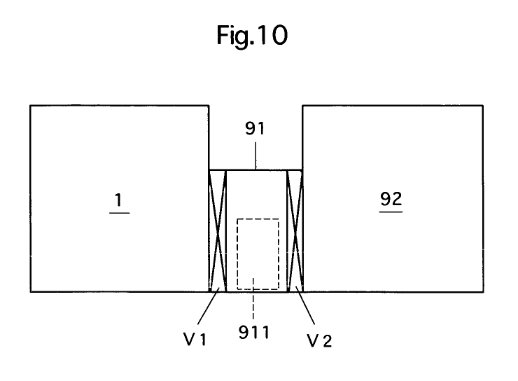

For example, as schematically shown in FIG. 10, a substrate transfer chamber 91 is communicated via a gate valve V1 with the chamber 1 shown in FIG. 5 or FIG. 8 where silicon dots are formed.

A chamber 92 for forming an insulating layer is communicated via a gate valve V2 with the chamber 1. In the chamber 92, the insulating layer L1, e.g., silicon oxide film (SiO₂), silicon nitride film (Si₃N₄), or a mixture film (Si—O—N) of silicon oxide (SiO₂) and silicon nitride (Si₃N₄) may be formed, and the substrate S provided with the insulating layer may be supplied into the chamber 1 without exposure it to the outside air by a substrate transfer robot 911 already known per se in the substrate transfer chamber 91.

In the chamber 1, silicon dots D are formed over the insulating layer L1 of the substrate S, whereby the substrate having silicon dots S1 can be formed with contamination of the insulating layer L1 suppressed.

Also, as to each of the substrates having silicon dots S2 to S4 of the type shown in FIGS. 2 to 4, the insulating layer(s) may be formed in a chamber forming such insulating layer.

The first insulating layer L21 in the substrate S2, the first insulating layer L31 in the substrate S3, and the first insulating layer L41 in the substrate S4 may not be those formed in the chamber 92 for forming an insulating layer but may be those formed on the substrates S in advance.

The insulating layer(s) (layer L22 in the substrate S2, layer L32 in the substrate S3 or layers L42, L43 in the substrate S4) may be those formed in the chamber 92.

The insulating layer may be formed in the silicon dot forming chamber if no inconvenience is caused in forming silicon dots and/or forming the insulating layer.

Insulating layers may be formed by known layer forming methods at a low temperature without causing thermal damage to the substrate S. For example, the layers can be formed at a low temperature by a plasma CVD method.

For example, when taking a case wherein a silicon oxide film (SiO₂) is formed on the substrate S by the plasma CVD method in the insulating layer forming chamber 92, specified amounts of silane gas (SiH₄) and oxygen gas are supplied into the chamber 92, and a power is applied to the gases in a specified film deposition pressure with an electrode such as a parallel flat plate-type electrode in the chamber 92 to generate plasma wherein the film of SiO₂ can be formed on the substrate S.

When a film of silicon nitride (Si₃N₄) is formed, the film can be formed in the same manner using a silane gas and an ammonia gas.

If a film is formed of a mixture (Si—O—N) of silicon oxide (SiO₂) and silicon nitride (Si₃N₄), the film can be formed in the same manner using a silane gas, an oxygen gas and an ammonia gas.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A substrate having silicon dots wherein at least one insulating layer and at least one group of silicon dots are formed on a substrate selected from a non-alkali glass substrate and a substrate made of a polymer material.

2. The substrate having silicon dots according to claim 1, wherein the insulating layer and the group of silicon dots are formed on the substrate selected from the non-alkali glass substrate and the substrate made of the polymer material in this order.

3. The substrate having silicon dots according to claim 1, wherein the insulating layers and said at least one group of silicon dots are formed alternately on the substrate selected from the non-alkali glass substrate and the substrate made of the polymer material.

4. The substrate having silicon dots according to claims 1, wherein the substrate selected from the non-alkali glass substrate and the substrate made of the polymer material has the same shape and the same dimensions as those of a commercially available silicon wafer.

5. The substrate having silicon dots according to claim 1, 2, 3 or 4, wherein the insulating layer is formed of at least one material selected from silicon oxide, silicon nitride, and a mixture of silicon oxide and silicon nitride.
